(19) United States
(12) Patent Application Publication
(10) Pub. No.: US 2012/0295404 A1
(43) Pub. Date: Nov. 22, 2012

(54) METHOD OF MANUFACTURING SEMICONDUCTOR PACKAGE

(75) Inventors: Joon Seok KANG, Suwon (KR); Young Do KWEON, Seoul (KR); Seung Wook PARK, Suwon (KR); Jong Yun LEE, Incheon (KR); Kyung Seob OH, Suwon (KR)

(73) Assignee: SAMSUNG ELECTRO-MECHANICS CO., LTD., Suwon (KR)

(21) Appl. No.: 13/557,362

(22) Filed: Jul. 25, 2012

Related U.S. Application Data
(62) Division of application No. 12/805,334, filed on Jul. 26, 2010.

(30) Foreign Application Priority Data
Nov. 12, 2009 (KR) 10-2009-0109027

(51) Int. Cl. H01L 21/58

(52) U.S. Cl. 438/125; 257/E21.505

(57) ABSTRACT

A method of manufacturing a semiconductor package, the method including: forming an insulating layer on a board; forming an electrode pattern portion by redistribution plating in order to make a circuit connection on the insulating layer; manufacturing a semiconductor chip by forming a protecting portion on the electrode pattern portion such that a portion of the electrode pattern portion is exposed; and mounting the semiconductor chip on a receiving space of a circuit board and electrically connecting the semiconductor chip to the circuit board.

### CROSS-REFERENCE TO RELATED APPLICATIONS

This application is a U.S. divisional application filed under 37 CFR 1.53(b) claiming priority benefit of U.S. Ser. No. 12/805,334 filed in the U.S. on Jul. 26, 2010, which claims earlier priority benefit to Korean Patent Application No. 10-2009-0109027 filed with the Korean Intellectual Property Office on Nov. 12, 2009, the disclosures of which are incorporated herein by reference.

### BACKGROUND

1. Field

The present invention relates to a semiconductor package and a manufacturing method thereof, and more particularly, to a semiconductor package allowing for a reduction in a manufacturing process due to no need for a separate bump process and a manufacturing method thereof.

2. Description of the Related Art

One of the main trends in industrial semiconductor technology development is the downsizing of a semiconductor device.

In order to realize lighter, thinner and smaller elements, there is the need for a method of reducing the individual sizes of mounted elements, a system on chip (SOC) technique allowing for a plurality of individual devices to be integrated into a single chip, a system in package (SIP) technique allowing for a plurality of individual devices to be integrated as a single package or the like. Such a realization may be achieved by rerouting or redistribution technology.

Therefore, such a semiconductor package enables a reduction in the length of a wiring connection between electronic elements and a realization of high-density wiring. Also, due to the mounting of electronic elements, a circuit board has an expanded surface area and superior electrical characteristics.

Particularly, in an embedded-type circuit board, a semiconductor chip is not mounted on the surface of the board, but is embedded therein. This enables the miniaturization, high-density, and high-performance of the board. Accordingly, the demand for this type of circuit board has increased.

However, this circuit board requires a plurality of wiring processes to connect an upper portion of the semiconductor chip to the circuit board, and accordingly, lengthy processing time and high cost are required. In this regard, demand has increased for economical advantages by reducing these processes. Therefore, technology for solving these problems is required.

### SUMMARY

An aspect of the present invention provides a semiconductor package allowing for a reduction in a manufacturing process and time by removing a process of forming a bump layer, and a method of manufacturing the semiconductor package.

According to an aspect of the present invention, there is provided a semiconductor package including: a circuit board having a receiving space formed therein; a semiconductor chip inserted into the receiving space of the circuit board; and an electrode pattern portion having a pattern shape on one surface of the semiconductor chip, and directly contacting a via portion of the circuit board so as to be electrically connected thereto.

The electrode pattern portion may have a thickness of 5 μm to 15 μm.

The semiconductor chip may include a protecting portion formed on a surface thereof and protecting the electrode pattern portion.

The protecting portion may have an open portion to expose a portion of the electrode pattern portion in contact with the via portion.

The semiconductor chip may have an insulating layer formed between the surface of the semiconductor chip and the electrode pattern portion.

According to another aspect of the present invention, there is provided a method of manufacturing a semiconductor package, the method including: forming an insulating layer on a board; forming an electrode pattern portion by redistribution plating in order to make a circuit connection on the insulating layer; manufacturing a semiconductor chip by forming a protecting portion on the electrode pattern portion such that a portion of the electrode pattern portion is exposed; and mounting the semiconductor chip on a receiving space of a circuit board and electrically connecting the semiconductor chip to the circuit board.

The electrode pattern portion may have a thickness of 5 μm to 15 μm.

The forming of the electrode pattern portion may include forming a copper layer on the insulating layer by sputtering.

The electrical connecting of the semiconductor chip to the circuit board may include forming a via hole connected to an upper portion of the electrode pattern portion from the circuit board and forming a via portion electrically connected by filling the via hole with a conductive material.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a semiconductor package according to an exemplary embodiment of the present invention;

FIG. 2 is a cross-sectional view illustrating a semiconductor chip mounted in the semiconductor package of FIG. 1; and

FIGS. 3 through 8 are cross-sectional views illustrating a method of manufacturing a semiconductor package according to an exemplary embodiment of the present invention.

### DESCRIPTION OF EMBODIMENTS

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the same reference numerals will be used throughout to designate the same or like elements.

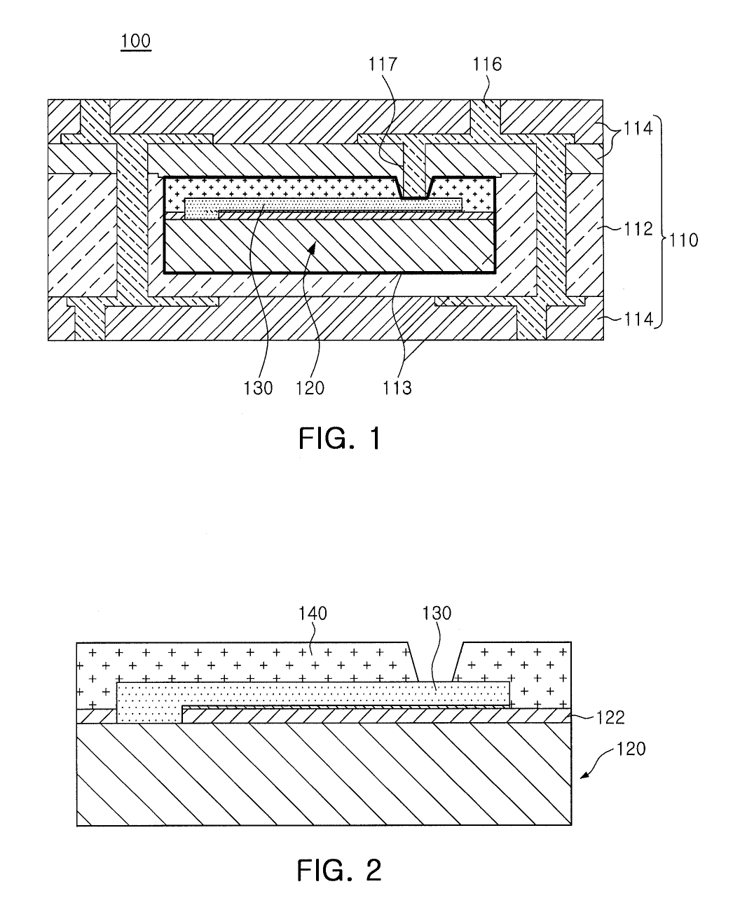

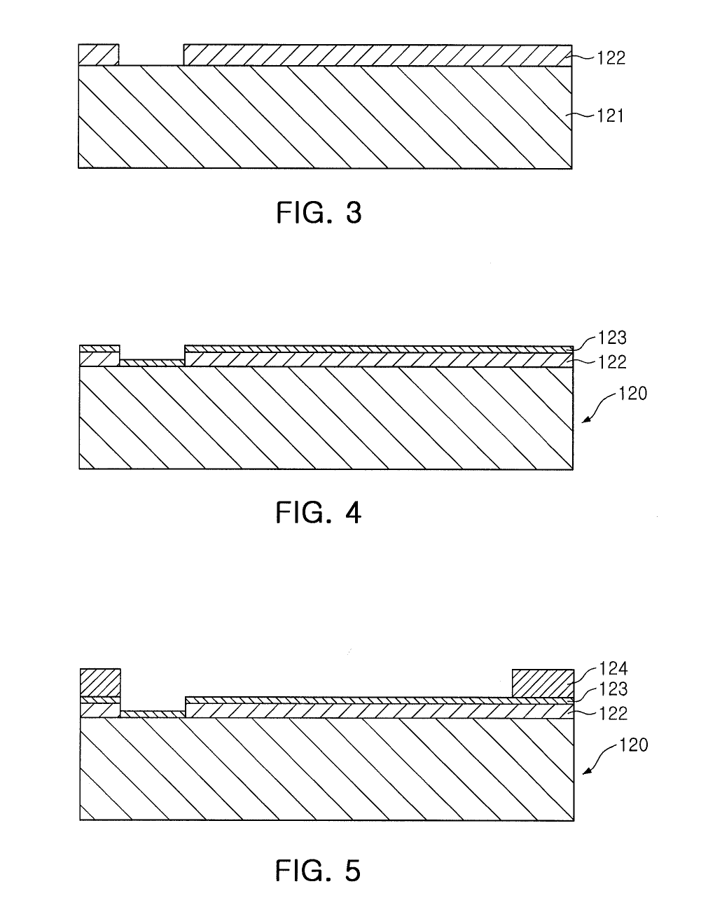

FIG. 1 is a cross-sectional view illustrating a semiconductor package according to an exemplary embodiment of the present invention. FIG. 2 is a cross-sectional view illustrating a semiconductor chip mounted in the semiconductor package of FIG. 1.

Referring to FIGS. 1 and 2, a semiconductor package 100 may include a circuit board 110, a semiconductor chip 120, and an electrode pattern portion 130.

The circuit board 110 may have at least one groove 113 formed therein in order to provide a receiving space for mounting the semiconductor chip 120 on a metallic core 112. As a method of forming the groove, dry etching or wet etching may be used.

After the semiconductor chip 120 is deposited in the receiving space, an insulating portion 114 having a predetermined thickness is formed thereon. This process allows the semiconductor chip 120, deposited at the inside of the circuit board 110, to be sealed.

A via portion 116 may be formed on the surface of the circuit board 110 to be electrically connected to the electrode pattern portion 130 formed on the surface of the semiconductor chip 120.

The via portion 116 may be formed by filling a via hole 117 with a conductive material after the via hole 117 is formed to expose the electrode pattern portion 130 to the outside. The via portion 116 may be electrically connected to a circuit pattern formed on the surface of the circuit board 110.

Here, the via hole 117 may be formed by a perforating method known in the art. A laser drilling method using carbon dioxide may be used to form the via hole 117.

The semiconductor chip 120 may be inserted into the receiving space of the circuit board 110 to be electrically connected to the via portion 116. Here, the semiconductor chip 120 may be provided as a plurality of semiconductor chips, and the plurality of semiconductor chips may be formed on a wafer. This semiconductor chip may be an active element, a passive element or an IC chip.

Here, the electrode pattern portion 130 may be formed on the semiconductor chip 120 by redistribution plating. This electrode pattern portion 130 is electrically connected to the via portion 116 to be thereby electrically connected to the circuit board 110.

The electrode pattern portion 130 is formed on one surface of the semiconductor chip 120. The electrode pattern portion 130 may have a pattern shape due to the redistribution plating. Here, the pattern shape may be a shape like circuit wires formed for electrical connection.

Here, the thickness of the electrode pattern portion 130 may be approximately 5 μm to 15 μm. Due to the electrode pattern portion 130 having such a thickness, the electrical resistance of the semiconductor chip 120 may be reduced. Also, electrical reliability is enhanced by this electrode pattern portion 130.

In general, when the semiconductor chip 120 is electrically connected to the circuit board 110, a separate bump layer is formed on the semiconductor chip 120. However, the electrode pattern portion 130 having the above thickness may remove electrical faults since the electrode pattern portion 130 does not expose the semiconductor chip 120 at the time of forming the via hole 117 in order that the electrode pattern portion 130 is directly connected to the via portion 116.

In the semiconductor package according to this embodiment, such a bump layer manufacturing process may be omitted. Accordingly, the number of process stages and processing time can be reduced, that is, a large economical effect is obtained. Such a reduction in the number of process stages leads to the improved manufacturing yield of the semiconductor package.

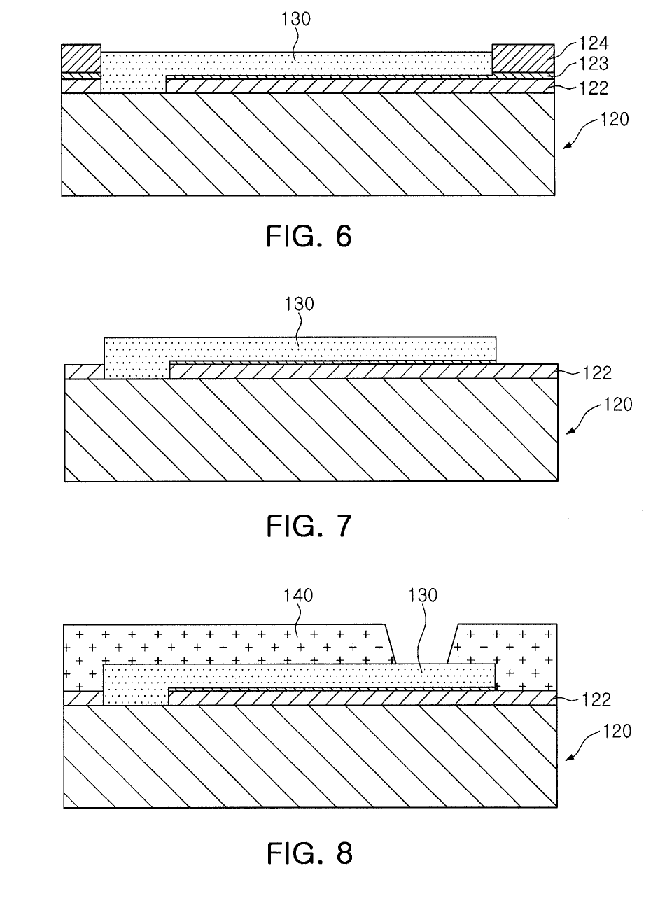

FIGS. 3 through 8 are cross-sectional views illustrating a method of manufacturing a semiconductor package according to an exemplary embodiment of the present invention.

Referring to FIG. 3, the method of manufacturing the semiconductor package according to this embodiment may include forming an insulating layer 122 on a board 121 formed of an insulating material.

Here, the insulating layer 122 may be formed to have an open portion to allow a pad formed on the board 121 to be exposed to the outside. The insulating layer 122 may be a photosensitive material and may include at least one selected from the group consisting of polyimide, polybenzooxazole, benzocyclobutene and epoxy. However, the material of the insulating layer 122 is not limited thereto.

As shown in FIG. 4, a plating layer 123 formed of copper (Cu) may be formed on the insulating layer 122 that is formed on one surface of the semiconductor chip 120. The plating layer 123 may be formed by sputtering.

The plating layer 123 may be formed on the entirety of the semiconductor chip 120, even on the open portion of the insulating layer 122.

As shown in FIG. 5, a photoresist layer 124 is formed, and then a portion of the photoresist layer 124 is removed by using a mask in order to form the electrode pattern portion 130.

As shown in FIG. 6, the electrode pattern portion 130 is formed in the removed portion of the photoresist layer 124 by electroplating. Here, the electrode pattern portion 130 may be generally formed by electroplating and sputtering.

The thickness of the electrode pattern portion 130 may be approximately 5 μm to 15 μm. Due to the electrode pattern portion 130 having such a thickness, the electrical resistance of the semiconductor chip 120 may be reduced. Further, electrical reliability is enhanced by this electrode pattern portion 130.

As shown in FIG. 7, the plating layer 123 and the photoresist layer 124, in which the electrode pattern portion 130 is not formed, are removed. Here, the removal is made by an etching or strip process.

Then, as shown in FIG. 8, a protecting portion 140 is formed at the upper part of the semiconductor chip 120 where the electrode pattern portion 130 is formed. Here, the protecting portion 140 may be a silicon nitride layer, a silicon oxide layer, a silicon acid nitride layer, or a multiple layer thereof. The protecting portion 140 may protect the electrode pattern portion 130 and the other circuit patterns.

A portion of the protecting portion 140 is open to expose the electrode pattern portion 130, and this open portion is connected to the via portion 116.

The semiconductor chip 120 formed as described above is mounted on the receiving space of the circuit board 110, thereby manufacturing a semiconductor package. This manufactured semiconductor package becomes a finished product by a process of making the thickness of a wafer thinner and a dicing process.

As a result, the semiconductor package according to this embodiment does not require a separate bump layer at the upper part of the semiconductor chip 120, the processes related to the manufacturing of the bump layer, such as forming a Cu-plating layer, preparing a photoresist layer, creating a pattern on the photoresist layer, bump plating, and removing the photoresist layer and the Cu-plating layer may all be omitted.

Therefore, the semiconductor package according to this embodiment has the large economical advantage of simplifying manufacturing processes. Also, a reduction in the number of process stages leads to enhanced manufacturing yield of the semiconductor package.

As set forth above, according to exemplary embodiments of the invention, the semiconductor package and the manufacturing method thereof includes the electrode pattern portion having a pattern shape on one surface of the semiconductor chip and directly contacting the via portion of the circuit board so as to be electrically connected thereto, so the processes related to the forming of the bump can be omitted. Accordingly, a reduction in the number of process stages and time is achieved.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a semiconductor package, the method comprising:
forming an insulating layer on a board;
forming an electrode pattern portion by redistribution plating in order to make a circuit connection on the insulating layer;
manufacturing a semiconductor chip by forming a protecting portion on the electrode pattern portion such that a portion of the electrode pattern portion is exposed; and
mounting the semiconductor chip on a receiving space of a circuit board and electrically connecting the semiconductor chip to the circuit board.

2. The method of claim 1, wherein the electrode pattern portion has a thickness of 5 μm to 15 μm.

3. The method of claim 1, wherein the forming of the electrode pattern portion comprises forming a copper layer on the insulating layer by sputtering.

4. The method of claim 1, wherein the electrical connecting of the semiconductor chip to the circuit board comprises:
forming a via hole connected to an upper portion of the electrode pattern portion from the circuit board; and
forming a via portion electrically connected by filling the via hole with a conductive material.
